(19) United States
(12) Patent Application Publication
(10) Pub. No.: US 2012/0104445 A1
(43) Pub. Date: May 3, 2012

(54) CHIP PACKAGE AND METHOD FOR FORMING THE SAME

(76) Inventors: Ming-Kun YANG, Pingzhen City (TW); Tsang-Yu LIU, Zhubei City (TW)

(21) Appl. No.: 13/288,812

(22) Filed: Nov. 3, 2011

Related U.S. Application Data
(60) Provisional application No. 61/409,852, filed on Nov. 3, 2010.

(51) Int. Cl. H01L 33/60

(52) U.S. Cl. 257/98; 438/27; 438/33; 257/E33.06

(57) ABSTRACT

An embodiment of the invention provides a chip package which includes: a substrate having a surface; a first conducting layer located on the surface; a second conducting layer located on the surface, wherein the first conducting layer and the second conducting layer are electrically insulated from each other; a first reflective layer conformally located on the first conducting layer and at least partially covering a side of the first conducting layer; a second reflective layer conformally located on the second conducting layer and at least partially covering a side of the second conducting layer; and a chip disposed on the surface of the substrate and having at least a first electrode and a second electrode, wherein the first electrode is electrically connected to the first conducting layer, and the second electrode is electrically connected to the second conducting layer.

### CROSS REFERENCE TO RELATED APPLICATIONS

This Application claims the benefit of U.S. Provisional Application No. 61/409,852, filed on Nov. 3, 2010, the entirety of which is incorporated by reference herein.

### BACKGROUND OF THE INVENTION

1. Field of the Invention

The invention relates to a chip package, and in particular relates to a light emitting chip package.

2. Description of the Related Art

A chip package is used to protect the chip packaged therein and provide conducting routes between the chip and electronic elements outside of the package. For a light emitting chip package, it is also desired to enhance light emitting efficiency thereof.

Although a reflective layer may be disposed neighboring the chip to reflect a light emitted by the light emitting chip for enhancing the light emitting efficiency, it is easy for the reflectance of the reflective layer to be reduced due to the influence from fabrication processes subsequent to forming of the reflective layer.

Thus, a technology which can enhance the light emitting efficiency of the light emitting chip package is desired.

### BRIEF SUMMARY OF THE INVENTION

An embodiment of the invention provides a chip package which includes: a substrate having a surface; a first conducting layer located on the surface; a second conducting layer located on the surface, wherein the first conducting layer and the second conducting layer are electrically insulated from each other; a first reflective layer conformally located on the first conducting layer and at least partially covering a side of the first conducting layer; a second reflective layer conformally located on the second conducting layer and at least partially covering a side of the second conducting layer; and a chip disposed on the surface of the substrate and having at least a first electrode and a second electrode, wherein the first electrode is electrically connected to the first conducting layer, and the second electrode is electrically connected to the second conducting layer.

An embodiment of the invention provides a method for forming a chip package which includes: providing a substrate; forming a plurality of first conducting layers and a plurality of second conducting layers on a surface of the substrate, wherein the first conducting layers and the second conducting layers are electrically insulated from each other, respectively; electroplating a first reflective layer on each of the first conducting layers, respectively, wherein the first reflective layer at least partially covers a side of a corresponding conducting layer of the first conducting layers; electroplating a second reflective layer on each of the second conducting layers, respectively, wherein the second reflective layer at least partially covers a side of a corresponding second conducting layer of the second conducting layers; disposing a plurality of chips on the surface of the substrate, wherein each of the plurality of chips has a first electrode and a second electrode; forming electrical connections between the first electrode of each of the plurality of chips and corresponding first conducting layer of the first conducting layers; forming electrical connections between the second electrode of each of the plurality of chips and corresponding second conducting layer of the second conducting layers; and dicing the substrate along a plurality of predetermined scribe lines defined on the substrate to form a plurality of chip packages.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1A-1F are cross-sectional views showing the steps of forming a chip package according to an embodiment of the present invention;

FIG. 2 is a cross-sectional view showing a chip package according to an embodiment of the present invention;

FIGS. 3A-3C are top views showing the substrate of embodiments of the invention, which are used to show the layouts of the conducting layers; and

FIGS. 4A-4D are top views showing the substrate of embodiments of the invention, which are used to show the layouts of the conducting layers on the substrate after a dicing process.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

The manufacturing method and method for use of the embodiment of the invention are illustrated in detail as follows. It is understood, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numbers and/or letters in the various examples. This repetition is for the purpose of simplicity and clarity and does not in itself dictate a relationship between the various embodiments and/or configurations discussed. Furthermore, descriptions of a first layer “on,” “overlying,” (and like descriptions) a second layer, include embodiments where the first and second layers are in direct contact and those where one or more layers are interposing the first and second layers.

A chip package according to an embodiment of the present invention may be used to package a light emitting element such as a light emitting diode chip. However, embodiments of the invention are not limited thereto. For example, the chip package of the embodiments of the invention may be applied to active or passive devices, or electronic components with digital or analog circuits, such as opto electronic devices, micro electro mechanical systems (MEMS), micro fluidic systems, and physical sensors for detecting heat, light, or pressure. Particularly, a wafer scale package (WSP) process may be applied to package semiconductor chips, such as image sensor devices, light-emitting diodes (LEDs), solar cells, RF circuits, accelerators, gyroscopes, micro actuators, surface acoustic wave devices, pressure sensors, ink printer heads, or power ICs.

The wafer scale package process mentioned above mainly means that after the package process is accomplished during the wafer stage, the wafer with chips is cut to obtain separate independent packages. However, in a specific embodiment, separate independent chips may be redistributed overlying a supporting wafer and then be packaged, which may also be referred to as a wafer scale package process. In addition, the above mentioned wafer scale package process may also be adapted to form chip packages of multi-layer integrated circuit devices by stacking a plurality of wafers having integrated circuits. In one embodiment, after the dicing process is performed, the obtained chip package is a chip scale package (CSP). The size of the chip scale package (CSP) may be only slightly larger than the size of the packaged chip. For example, the size of the chip scale package is not larger than 120% of the size of the packaged chip.

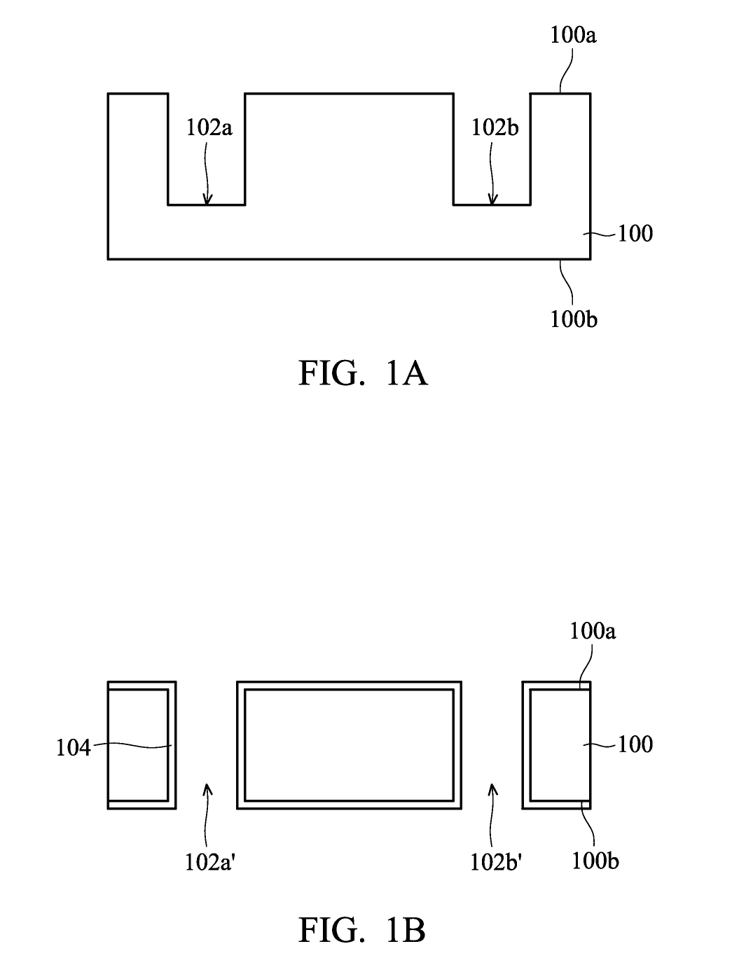

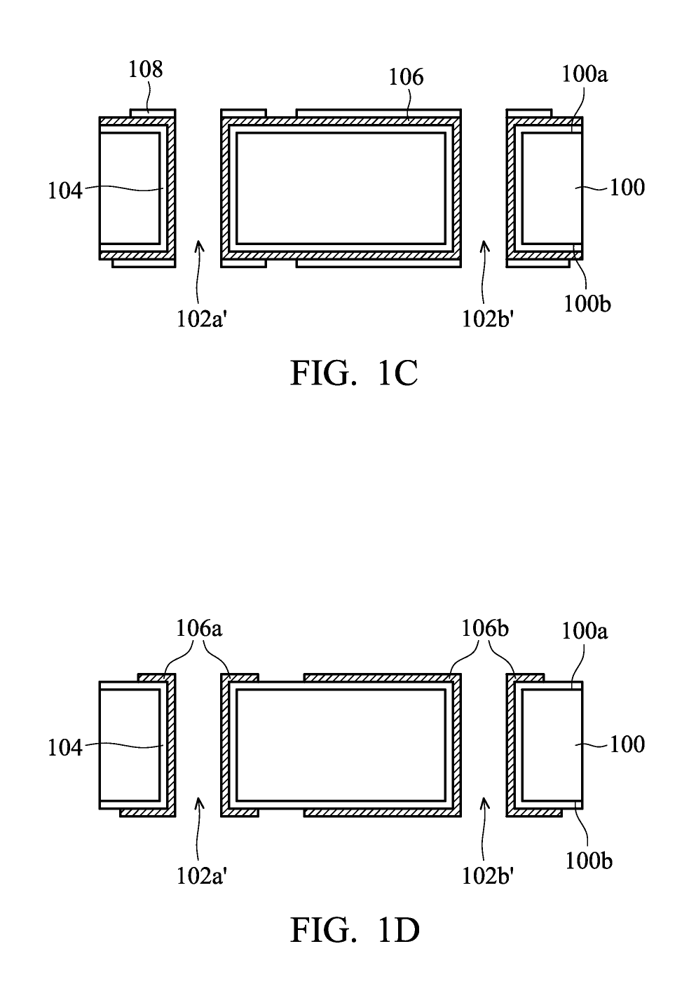

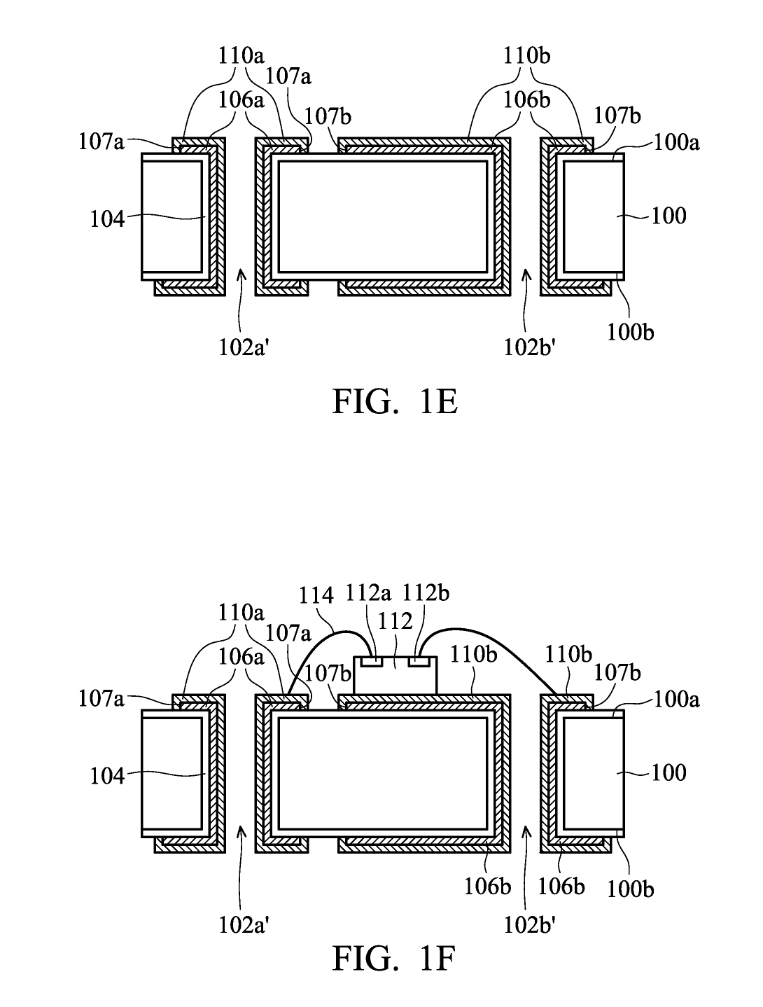

FIGS. 1A-1F are cross-sectional views showing the steps for forming a chip package according to an embodiment of the present invention. As shown in FIG. 1A, a substrate 100 is provided. In one embodiment, the substrate 100 is a semiconductor wafer (such as a silicon wafer), and a wafer-level packaging process may be performed to reduce fabrication time and cost. The substrate 100 has a surface 100a and a surface 100b. The surfaces 100a and 100b may be, for example, opposite to each other.

In one embodiment, a through substrate conducting structure may be optionally formed in the substrate 100 to electrically connect elements disposed on the two surfaces of the substrate 100. For example, a portion of the substrate 100 may be optionally removed from the surface 100a of the substrate 100 to form a hole 102a and a hole 102b extending from the surface 100a towards the surface 100b. In a wafer-level packaging process, a plurality of holes 102a and a plurality of holes 102b may be formed. The hole may be formed by using, for example, a photolithography process and an etching process.

Next, as shown in FIG. 1B, the substrate 100 may be thinned from the surface 100b of the substrate 100 to expose the hole 102a and the hole 102b, thus forming a through-hole 102a′ and a through-hole 102b′. The substrate 100 may be thinned to a suitable thickness according to requirements. A suitable thinning process may include (but is not limited to) a mechanical grinding process or a chemical mechanical polishing process.

Then, an insulating layer 104 may be optionally formed on the surface of the substrate 100 and the sidewalls of the through-hole 102a′ and the through-hole 102b′. In one embodiment, the insulating layer 104 may be (but is not limited to) a thermal oxidation layer. For example, if the substrate 100 is a silicon wafer, the insulating layer 104 may be a silicon oxide layer formed on the surface of the silicon wafer by using a thermal oxidation process. The insulating layer 104 may also be formed by using another suitable manufacturing process and/or another suitable material. For example, the material of the insulating layer 104 may include a polymer material such as epoxy resin, polyimide, or combinations thereof. The material of the insulating layer 104 may also include an oxide, nitride, oxynitride, metal oxide, or combinations thereof. The formation method of the insulating layer 104 may include, for example, a spray coating process, printing process, dipping process, chemical vapor deposition process, or combinations thereof.

As shown in FIG. 1C, a seed layer 106 is then formed on the surface 100a and the surface 100b of the substrate 100 and the sidewalls of the through-hole 102a′ and the through-hole 102b′. In one embodiment, the seed layer 106 substantially and completely covers the surface of the substrate 100. The seed layer 106 is typically a conductive material suitable for being electroplated with a conducting material. Next, as shown in FIG. 1C, a patterned mask layer 108 is formed on the seed layer 106. The patterned mask layer 108 may be defined to have a plurality of openings. The openings expose a portion of the seed layer 106.

Next, as shown in FIG. 1D, the portion of the seed layer 106 exposed by the openings of the patterned mask layer 108 is removed to form the conducting layer 106a and the conducting layer 106b on the substrate, wherein the conducting layer 106a is electrically insulated from the conducting layer 106b. In a wafer-level packaging process, a plurality of conducting layers 106a and a plurality of conducting layers 106b are formed. In the embodiment shown in FIG. 1D, both the conducting layer 106a and the conducting layer 106b respectively extend into the through-holes and extend on the surface 100b of the substrate 100. Then, the patterned mask layer 108 is removed.

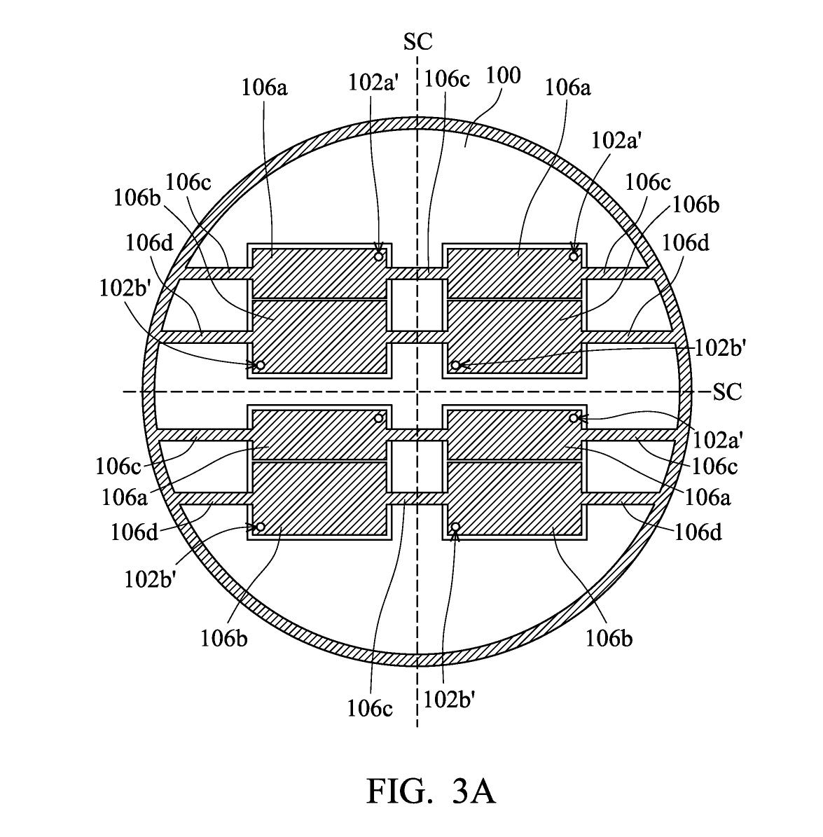

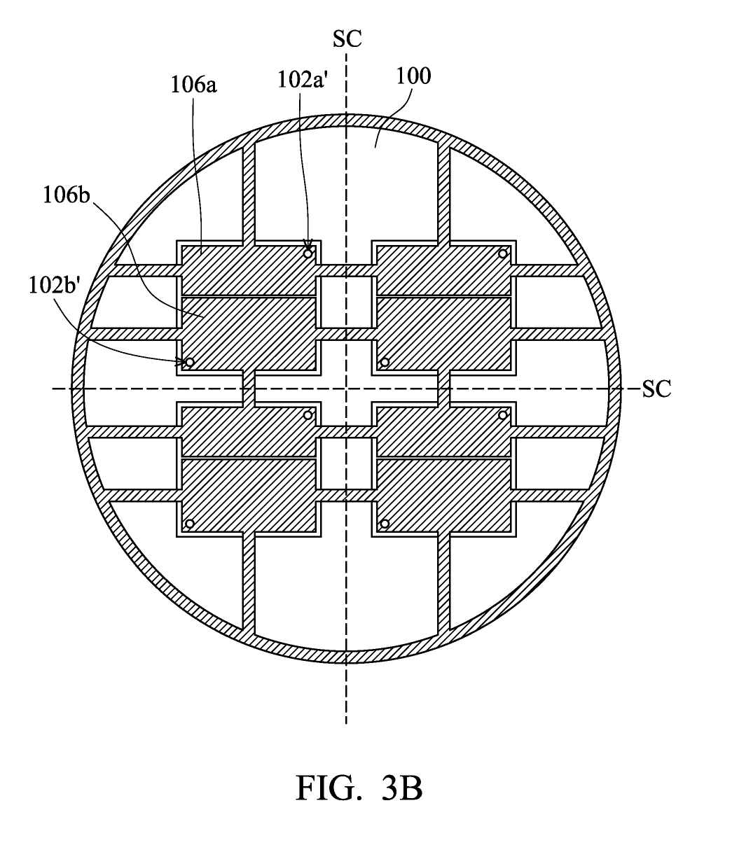

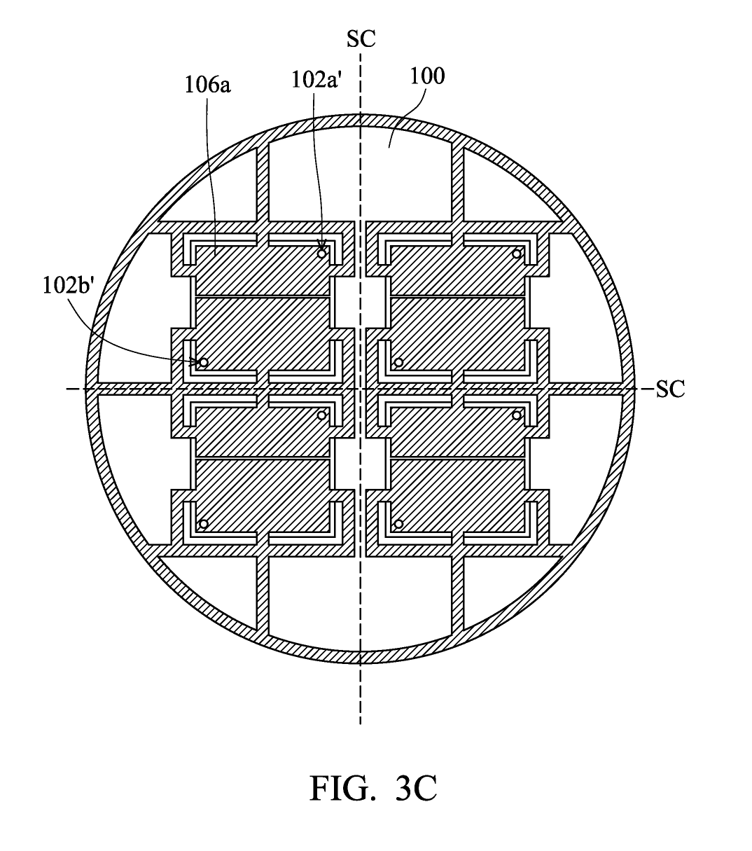

FIG. 3A is a top view showing the substrate according to an embodiment of the present invention, which is used to illustrate the layout of the conducting layers and may correspond to the embodiment shown in FIG. 1D. As shown in FIG. 3A, the substrate 100 has a plurality of predetermined scribe lines SC which define the substrate 100 into a plurality of regions. It should be appreciated that although in FIG. 3A the substrate is defined into four regions by two scribe lines, one skilled in the art should understand that in a wafer level packaging process the substrate 100 may have more predetermined scribe lines SC defined thereon. After a following dicing process, a plurality of chip packages may be simultaneously formed.

As shown in FIG. 3A, when the exposed seed layer 106 is removed to form the plurality of conducting layers 106a and the plurality of the conducting layers 106b, a plurality of electroplating wires 106c and a plurality of electroplating wires 106d may be simultaneously defined. The electroplating wires 106c are respectively formed between neighboring conducting layers 106a, and the electroplating wires 106d are respectively formed between neighboring conducting layers 106b. That is, the conducting layers 106a may be electrically connected to each other through the electroplating wires 106c therebetween. The conducting layers 106b may be electrically connected to each other through the electroplating wires 106d therebetween.

Next, referring to FIGS. 1E and 3A, a reflective layer 110a is electroplated on each of the conducting layers 106a, and a reflective layer 110b is electroplated on each of the conducting layers 106b. In one embodiment, the substrate 100 such as that shown in FIG. 1E or 3A is disposed in an electroplating solution in an electroplating tank (not shown). A current is applied through the conducting layers 106a and the conducting layers 106b such that metal ions in the electroplating solution are reduced on the conducting layers 106a and the conducting layers 106b and deposited to be the reflective layer 110a and the reflective layer 110b. In one embodiment, the reflective layer 110a and the reflective layer 110b are simultaneously formed such as simultaneously formed in a same electroplating process. In this case, the materials of the reflective layer 110a and the reflective layer 110b are the same. Further, the reflective layer 110a directly contacts with the conducting layers 106a, and the reflective layer 110 directly contacts with the conducting layers 106b.

The material of the reflective layer 110a or the reflective layer 110b may include (but is not limited to) silver, palladium, platinum, or combinations thereof. In one embodiment, the reflective layer 110a and the reflective layer 110b are used to reflect a light emitted by a light emitting chip which will be subsequently disposed on the surface 100a of the substrate 100, thus improving the light emitting efficiency of the chip package. Thus, it is preferable that the material of the reflective layer 110a and the reflective layer 110b is chosen to have high reflectance. In one embodiment, a reflectance of the reflective layer 110a or the reflective layer 110b to the light emitted by the light emitting chip is larger than a reflectance of the conducting layers 106a or the conducting layers 106b to the light emitted by the light emitting chip. In this case, the material of the reflective layer (the reflective layer 110a or the reflective layer 110b) is different from the material of the conducting layers 106a or the conducting layers 106b. In addition, the reflective layer 110a and the reflective layer 110b not only help to improve the light emitting intensity but also have electrical conductivity and may serve as redistribution layers. Further, in one embodiment, the reflective layer 110a does not directly contact with the reflective layer 110b.

Referring to FIG. 1E, because the reflective layer 110a and the reflective layer 110b are conformally formed on the conducting layers 106a and 106b by electroplating, respectively, sides 107a and 107b of the conducting layers 106a and 106b are also electroplated with the reflective layer 110a and the reflective layer 110b, respectively. That is, the reflective layer 110a at least partially covers the side 107a of the corresponding conducting layer 106a. Similarly, the reflective layer 110b at least partially covers the side 107b of the corresponding conducting layer 106b.

In the embodiment shown in FIG. 1E, although the reflective layer 110a and the reflective layer 110b completely cover the side 107a of the conducting layer 106a and the side 107b of the conducting layer 106b, respectively, embodiments of the invention are not limited thereto. In another embodiment, due to the difference of the electroplating conditions, the reflective layer 110a may not completely cover the side 107a of the conducting layer 106a such that a portion of the side 107a is exposed. Further, because the current density on the side 107a of the conducting layer 106a may be smaller when performing the electroplating process, the thickness of the reflective layer 110a electroplated on the side 107a of the conducting layer 106a is usually smaller than the thickness of the reflective layer 110a electroplated on the upper surface of the conducting layer 106a. For the reflective layer 110b, the reflective layer 110b may also have a profile similar to that of the reflective layer 110a.

As shown in FIG. 1F, a plurality of chips 112 may then be disposed on the surface 100a of the substrate 100, which may be (but is not limited to) light emitting chips. The chip 112 has at least an electrode 112a and at least an electrode 112b. If the chip 112 is a light emitting diode chip, the electrode 112a may be a p-type electrode, and the electrode 112b may be an n-type electrode. Alternatively, in another embodiment, the electrode 112a may be an N electrode, and the electrode 112b may be a P electrode.

Next, electrical connections between each of the electrodes 112a of the chips 112 and the conducting layer 106a are formed, and electrical connections between each of the electrodes 112b of the chips 112 and the conducting layer 106b are formed. In one embodiment, a bonding wire 114 may be formed between the reflective layer 110a and the electrode 112a. Because the reflective layer 110a is electrically connected to the conducting layer 106a, the electrode 112a of the chip 112 may be electrically connected to the conducting layer 106a, wherein the electrical connection may be led to the surface 100b of the substrate 100 through the through substrate conducting structure in the through-hole 102a′, facilitating following processes such as (but is not limited to) a flip-chip bonding process. Similarly, a bonding wire 114 may also be formed between the electrode 112b of the chip 112 and the reflective layer 110b, thus forming the electrical connection between the electrode 112b and the conducting layer 106b.

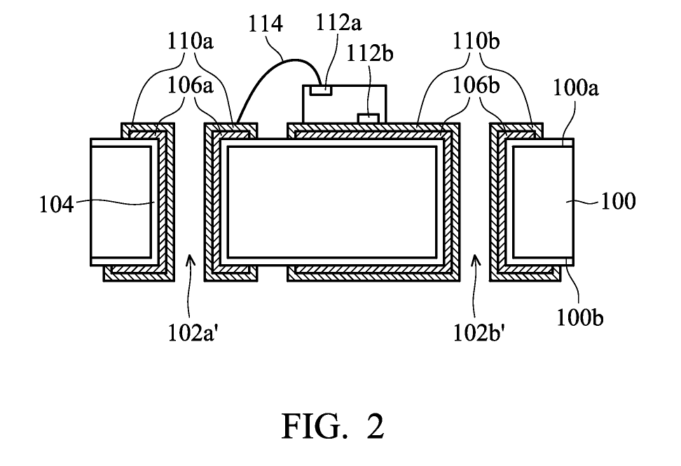

In addition, the electrodes 112a and 112b of the chip 112 are not only located on a same side of the chip 112, but may also be located on opposite sides of the chip 112, as shown in the embodiment in FIG. 2. In this case, the electrode 112a may be electrically connected to the conducting layer 106a through the bonding wire 114 and the reflective layer 110a. The electrode 112b may be disposed directly on the reflective layer 110b to electrically connect the conducting layer 106b.

Next, the substrate 100 is diced along the predetermined scribe lines SC defined on the substrate 100 (such as those shown in FIG. 3A) to form a plurality of chip packages. As shown in FIG. 3A, in one embodiment, after the step of dicing the substrate 100, at least some of the electroplating wires 106c are cut and separated into at least two sections, and at least some of the electroplating wires 106d are cut and separated into at least two sections.

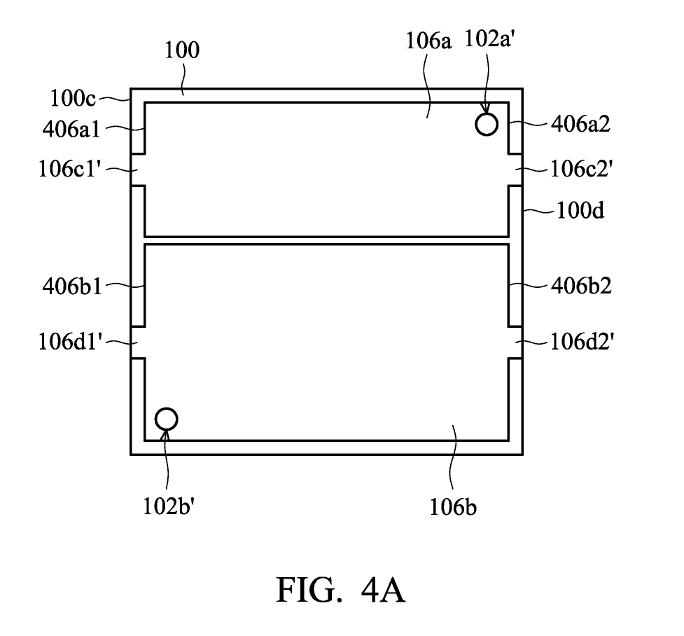

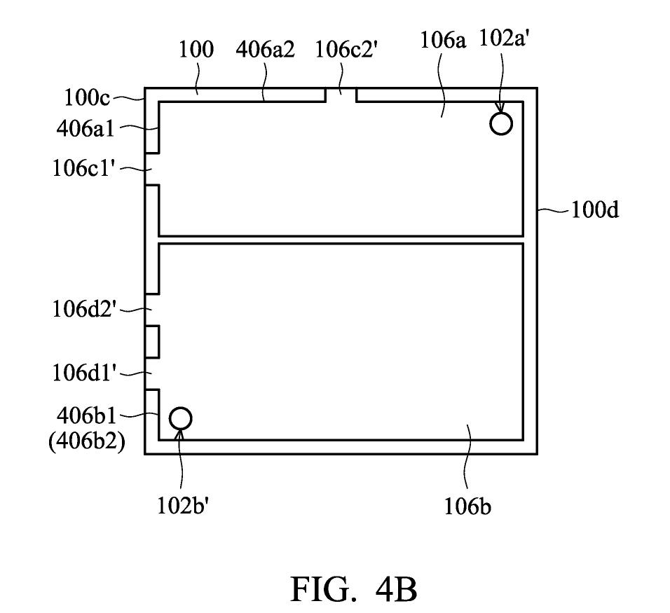

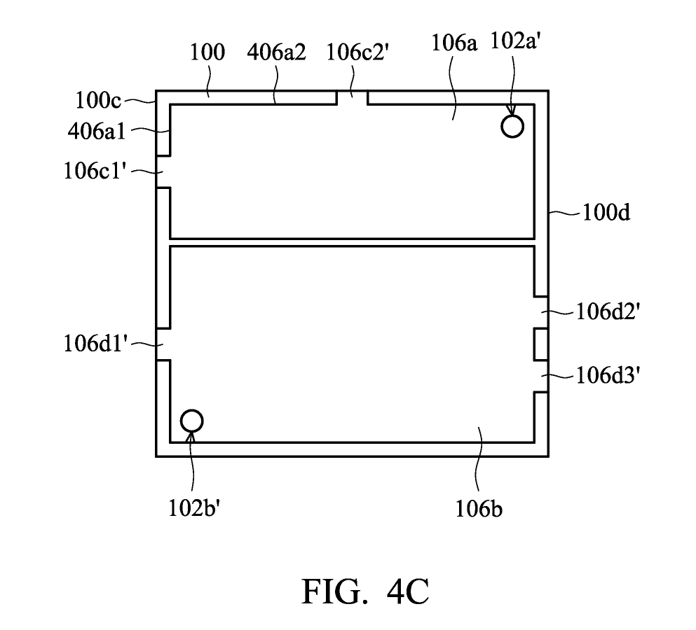

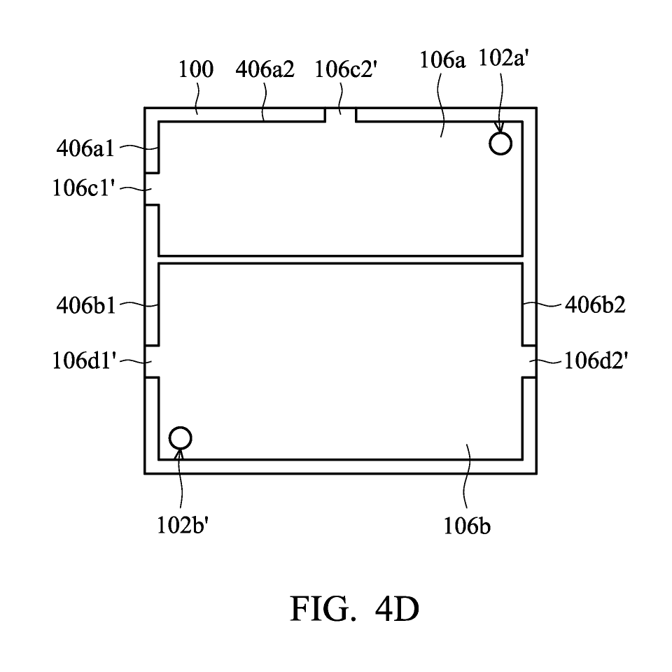

FIG. 4A is a top view showing a single chip package after the dicing process is performed, wherein the reflective layer, the chip, and the electrical connection between the chip and the conducting layer are not shown in the drawing for the convenience of showing the layout of the conducting layer on the substrate after the dicing process. As mentioned above, after the dicing process is performed, the electroplating wire is cut into at least two separate sections, wherein one of the sections may remain in the chip package. In the following description, the remaining portion is called an electroplating conducting pattern.

As shown in FIG. 4A, the chip package includes at least an electroplating conducting pattern 106c1′ and at least an electroplating conducting pattern 106c2′, located on the substrate 100 and extending from a first edge 406a1 and a second edge 406a2 of the conducting layer 106a towards a first edge 100c and a second edge 100d of the substrate 100, respectively. The chip package further includes at least an electroplating conducting pattern 106d1′ and at least an electroplating conducting pattern 106d2′, located on the substrate 100 and extending from a first edge 406b1 and a second edge 406b2 of the conducting layer 106b towards a third edge and a fourth edge of the substrate 100, respectively. In the embodiment shown in FIG. 4A, the third edge of the substrate is the first edge 100c, and the fourth edge of the substrate is the second edge 100d.

In the embodiments of the invention, a patterning process is first performed to the seed layer, and then an electroplating process is performed on the patterned seed layer (i.e., the conducting layer) such that the electroplated reflective layer naturally has a desired pattern with no need for an additional patterning process. Thus, the formed reflective layer in the embodiments of the invention will not be exposed under chemical substances, which may be used in a patterning process, such as a photoresist and an etchant. Thus, the reflective layer in the embodiments of the invention can still keep sufficient brightness to enhance the light emitting efficiency of the chip package. Further, through the formation of the electroplating wires, a wafer level packaging process may be performed to simultaneously form a plurality of chip packages with stable quality. Thus, fabrication cost and time are reduced.

In addition to what has been mentioned above, embodiments of the invention may have a variety of variations. For example, the layout of the conducting layer is not limited to that shown in FIG. 3A and may be varied according to the situation. FIGS. 3B-3C are top views showing the substrates according to other embodiments of the invention, which are used to illustrate the layouts of the conducting layers. As shown in FIGS. 3B and 3C, the conducting layers 106a may be connected to each other through a variety of types and layouts of the electroplating wires. Any layout of the conducting layer 106a which can form the reflective layer 110a on the substrate 100 in a same electroplating process is within the scope of embodiments of the invention. Similarly, the conducting layers 106b may be connected to each other through a variety of types and layouts of the electroplating wires.

FIGS. 4B-4D are top views showing a single chip package after the dicing process is performed according to other embodiments of the invention, wherein the reflective layer, the chip, the electrical connection between the chip and the conducting layer are not shown in the drawing for the convenience of showing the layout of the conducting layer on the substrate after the dicing process. Since the electroplating wires may have many variations, the electroplating conducting patterns in the chip package may also have many variations.

For example, the electroplating conducting pattern 106c1′ and the electroplating conducting pattern 106c2′ are not limited to extend from different edges of the conducting layer 106a. In one embodiment, at least two electroplating conducting patterns connecting a same conducting layer extend from a same edge of the conducting layer, as shown in the embodiment in FIG. 4B or 4C. Take the embodiment in FIG. 4B as an example, the electroplating conducting pattern 106d1′ and the electroplating conducting pattern 106d2′ extend from a same edge of the conducting layer 106b towards a same edge of the substrate 100. Further, the number of the electroplating conducting patterns connecting a same conducting layer is not limited to be two. For example, in the embodiment in FIG. 4C, the number of the electroplating conducting patterns connecting the conducting layer 106b is three, which are electroplating conducting patterns 106d1′, 106d2′ and 106d3′, respectively. In addition, the electroplating conducting patterns connecting a same conducting layer are not limited to be located on opposite edges of the conducting layer. For example, in the embodiment in FIG. 4B, the electroplating conducting patterns 106c1′ and 106c2′ are located on the edge 406a1 and the edge 406a2 of the conducting layer 106, respectively, wherein the edge 406a1 and the edge 406a2 are not opposite to each other and may be substantially perpendicular to each other. Variations of embodiments of the invention are not limited to the embodiments mentioned above.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a substrate having a surface;
a first conducting layer located on the surface;
a second conducting layer located on the surface, wherein the first conducting layer is electrically insulated from the second conducting layer;
a first reflective layer conformally located on the first conducting layer and at least partially covering a side of the first conducting layer;
a second reflective layer conformally located on the second conducting layer and at least partially covering a side of the second conducting layer; and
a chip disposed on the surface of the substrate and having at least a first electrode and a second electrode, wherein the first electrode is electrically connected to the first conducting layer, and the second electrode is electrically connected to the second conducting layer.

2. The chip package as claimed in claim 1, wherein the first reflective layer completely covers the side of the first conducting layer.

3. The chip package as claimed in claim 1, wherein the second reflective layer completely covers the side of the second conducting layer.

4. The chip package as claimed in claim 1, wherein the material of the first reflective layer and the material of the second reflective layer are the same.

5. The chip package as claimed in claim 4, wherein the material of the first reflective layer is different from the material of the first conducting layer or the second conducting layer.

6. The chip package as claimed in claim 5, wherein the chip is a light emitting chip, and a reflectance of the first reflective layer to a light emitted from the light emitting chip is larger than a reflectance of the first conducting layer or the second conducting layer to the light emitted from the light emitting chip.

7. The chip package as claimed in claim 1, further comprising an insulating layer located between the substrate and the first conducting layer and located between the substrate and the second conducting layer.

8. The chip package as claimed in claim 1, further comprising:
at least a first electroplating conducting pattern and at least a second electroplating conducting pattern located on the substrate and extending from a first edge and a second edge of the first conducting layer towards a first edge and a second edge of the substrate, respectively; and
at least a third electroplating conducting pattern and at least a fourth electroplating conducting pattern located on the substrate and extending from a first edge and a second edge of the second conducting layer towards a third edge and a fourth edge of the substrate, respectively.

9. The chip package as claimed in claim 8, wherein the first edge and the second edge of the first conducting layer are the same edge of the first conducting layer.

10. The chip package as claimed in claim 8, wherein the first edge and the second edge of the second conducting layer are the same edge of the second conducting layer.

11. The chip package as claimed in claim 8, wherein at least some of the first edge, the second edge, the third edge, and the fourth edge of the substrate are the same edge of the substrate.

12. The chip package as claimed in claim 1, further comprising:
a first through-hole extending from the surface towards a second surface of the substrate; and
a second through-hole extending from the surface towards the second surface of the substrate, wherein
the first conducting layer and the first reflective layer extend into the first through-hole and extend on the second surface, and
the second conducting layer and the second reflective layer extend into the second through-hole and extend on the second surface.

13. The chip package as claimed in claim 1, wherein the first conducting layer directly contacts with the first reflective layer, and the second conducting layer directly contacts with the second reflective layer.

14. The chip package as claimed in claim 1, wherein the first reflective layer does not directly contact with the second reflective layer.

15. A method for forming a chip package, comprising:
providing a substrate;
forming a plurality of first conducting layers and a plurality of second conducting layers on a surface of the substrate, wherein the first conducting layers and the second conducting layers are electrically insulated from each other, respectively;
electroplating a first reflective layer on each of the first conducting layers, respectively, wherein the first reflective layer at least partially covers a side of a corresponding first conducting layer of the first conducting layers;
electroplating a second reflective layer on each of the second conducting layers, respectively, wherein the second reflective layer at least partially covers a side of a corresponding second conducting layer of the second conducting layers;
disposing a plurality of chips on the surface of the substrate, wherein each of the plurality of chips has a first electrode and a second electrode;
forming electrical connections between the first electrode of each of the plurality of chips and corresponding first conducting layer of the first conducting layers;
forming electrical connections between the second electrode of each of the plurality of chips and corresponding second conducting layer of the second conducting layers; and
dicing the substrate along a plurality of predetermined scribe lines defined on the substrate to form a plurality of chip packages.

16. The method for forming a chip package as claimed in claim 15, wherein the formation steps of the first conducting layers and the second conducting layers comprises:
forming a seed layer on the surface of the substrate;
forming a patterned mask layer on the seed layer, wherein a portion of the seed layer is exposed;
removing the exposed portion of the seed layer to form the first conducting layers and the second conducting layers; and
removing the patterned mask layer.

17. The method for forming a chip package as claimed in claim 16, wherein the step of removing the exposed portion of the seed layer further comprises simultaneously forming a plurality of first electroplating wires and a plurality of second electroplating wires, the first electroplating wires are respectively formed between the neighboring first conducting layers, and the second electroplating wires are respectively formed between the neighboring second conducting layers.

18. The method for forming a chip package as claimed in claim 17, wherein after the step of dicing the substrate is performed, at least some of the first electroplating wires are separated into at least two sections, and at least some of the second electroplating wires are separated into at least two sections.

19. The method for forming a chip package as claimed in claim 15, wherein the first reflective layer and the second reflective layer are simultaneously formed.

20. The method for forming a chip package as claimed in claim 15, wherein the chips comprise a light emitting chip, and a reflectance of the first reflective layer to a light emitted from the light emitting chip is larger than a reflectance of the first conducting layer or the second conducting layer to the light emitted from the light emitting chip.
